(19) United States
(12) Patent Application Publication
(10) Pub. No.: US 2006/0118896 A1
(43) Pub. Date: Jun. 8, 2006

(54) Photodetector and method of manufacturing the same

(75) Inventors: Shin Jae Kang, Kyunggi-do (KR); Kyoung Soo Kwon, Kyunggi-do (KR); Joo Yul Ko, Kyunggi-do (KR)

Correspondence Address: DARBY & DARBY P.C., P. O. BOX 5257, NEW YORK, NY, 10150-5257, US

(73) Assignee: Samsung Electro-Mechanics Co., Ltd., Kyunggi-do (KR)

(21) Appl. No.: 11/056,701

(22) Filed: Feb. 11, 2005

(30) Foreign Application Priority Data
Dec. 8, 2004 (KR) 2004-103122

(51) Int. Cl. H01L 27/14

(52) U.S. Cl. 257/431

(57) ABSTRACT

Disclosed herein is a photodetector suitable for use in an optical pickup reproducing apparatus, which is capable of detecting short-wavelength light (e.g., light of about 405 nm) from storage media having large capacity, such as BD, with a high efficiency at a high speed, and a method of manufacturing the same.

### INCORPORATION BY REFERENCE

The present application claims priority under 35 U.S.C. §119 to Korean Patent Application No. 2004-103122 filed on Dec. 8, 2004. The content of the application is incorporated herein by reference in its entirety.

### BACKGROUND OF THE INVENTION

1. Field of the Invention

The present invention relates generally to a photodetector and a method of manufacturing the same. More specifically, the present invention relates to a photodetector suitable for use in an optical pickup reproducing apparatus, which is capable of detecting short-wavelength light (e.g., light of about 405 nm) from storage media having large capacity, such as BD (Blue-ray Disc), with a high efficiency at a high speed, and a method of manufacturing the same.

2. Description of the Related Art

In recent years, optical storage techniques have advanced toward high density, high speed and miniaturization while technically competing with memory devices, hard discs and magnetic discs. Further, the above techniques are becoming increasingly important owing to characteristics that distinguish them from other storage media.

The optical storage technique uses optical storage media (e.g., optical disc) which are removable from a disc drive and have advantages, such as lower prices and permanent data storage, compared to other storage media. In particular, the optical storage media are known to have much higher resistance to temperature and impact than other storage media.

Although the optical storage technique is disadvantageous because of low transmission rate and small storage capacity, it has recently been developed to realize high capacity and high speed comparable to magnetic discs in accordance with rapid technical progress. Nowadays, thorough research into photodetector integrated circuits to transform the received light into electric signals in the optical storage media is being conducted.

FIG. 1 is a view schematically showing a general photodetector integrated circuit.

In the photodetector integrated circuit shown in FIG. 1, a photodetector 1 absorbs light 3 to generate current I_{P}. The current I_{P} is transformed into the voltage through an amplifier 2, such as TIA (Trans-Impedance Amplifier), and then amplified. For example, when the current I_{P} is applied to the TIA, the voltage V_{OUT} discharged from the TIA is calculated as represented by Equation 1, below:

$${V}_{OUT} = ( 1 + \frac{{R}_{2}}{{R}_{1}} ) ( {V}_{C} + {I}_{P} {R}_{V} ) \qquad Equation 1$$

Wherein R_{V} is a variable resistance of an I-V amplifier (I-V AMP), R₁ and R₂ are resistances of a driving device (DRV), and V_{C} is a driving voltage.

Of the optical storage techniques manifesting high capacity and high speed, extensive and intensive research into photodetectors of photodetector integrated circuits to absorb light of about 405 nm to be transformed into electric signals is being conducted.

FIG. 2 is a sectional view of a conventional photodetector which is disclosed in Japanese Patent Laid-open Publication No. 2001-320075. FIG. 3 is a graph showing optical efficiency and frequency characteristics varying with finger spaces in the conventional photodetector, in which the frequency characteristics are obtained by measuring the frequency of 3 dB at which a gain varying with the frequency is halved.

As shown in FIG. 2, the photodetector disclosed in Japanese Patent Laid-open Publication No. 2001-320075 comprises an N⁻-type semiconductor layer 10 containing an N-type impurity at low concentration, a P⁺-type semiconductor layer 11 completely embedded in the N⁻-type semiconductor layer 10 and containing a P-type impurity at high concentration, and a protective film formed on the whole upper surface of the N⁻-type semiconductor layer 10 and the P⁺-type semiconductor layer 11. The P⁺-type semiconductor layer 11 has a width La, and the P⁺-type semiconductor layers 11 have spaces Lb therebetween. The photodetector disclosed in Japanese Patent Laid-open Publication No. 2001-320075 is advantageous because it effectively detects light of 780 nm or 650 nm.

As shown in FIG. 3, in the photodetector disclosed in Japanese Patent Laid-open Publication No. 2001-320075, the region able to absorb light is enlarged in proportion to increasing the finger spaces (that is, spaces Lb between the P⁺-type semiconductor layers 11). Thus, the above photodetector can exhibit high optical efficiency 31 for light of about 405 nm. However, the wider finger spaces result in increasing the moving distance of electron-hole pairs created by light absorption, and inducing a low electric field between the fingers (P⁺-type semiconductor layers 11). Hence, since the moving time of electrons or holes lengthens, the above photodetector cannot be used for a high frequency. Consequently, the frequency characteristics 32 become decreased due to the wider finger spaces.

On the other hand, in the photodetector disclosed in Japanese Patent Laid-open Publication No. 2001-320075, while the finger spaces are reduced, the mobile distance of electrons or holes formed between the fingers 104 and 105 is decreased and a high electric field is induced therebetween, therefore increasing the frequency characteristics 32. However, since the region able to absorb light diminishes in proportion to reducing the finger spaces, the optical efficiency 31 for light of about 405 nm is remarkably lowered.

Therefore, the photodetector disclosed in Japanese Patent Laid-open Publication No. 2001-320075, which has optical efficiency 31 and the frequency characteristics 32 that vary with the finger spaces as mentioned above, is applicable to low speed (e.g., 1× speed) BD optical reproducing apparatuses, however it cannot be used in high speed (e.g., 2× speed or more) BD optical reproducing apparatuses requiring high optical efficiency and high frequency characteristics.

### SUMMARY OF THE INVENTION

Accordingly, the present invention has been made keeping in mind the above problems occurring in the related art, and an object of the present invention is to provide a photodetector which can manifest high optical efficiency and high frequency characteristics for the short-wavelength light of about 405 nm.

Another object of the present invention is to provide a method of manufacturing such a photodetector.

In order to accomplish the above objects, the present invention provides a photodetector, comprising a substrate to support upper layers; an epitaxial layer formed on the substrate; at least one heavily doped first type finger partially embedded in the epitaxial layer to a small depth; at least one heavily doped second type finger partially embedded in the epitaxial layer to a small depth; a first type well formed in the epitaxial layer which is disposed outside the heavily doped first type fingers and the heavily doped second type fingers; a heavily doped first type electrode unit partially embedded in the first type well to a small depth; and a circuit unit formed on the heavily doped first type electrode unit, wherein the first type and the second type are doped with opposite type elements.

Preferably, the photodetector according to the present invention further comprises a regrown epitaxial layer formed on the epitaxial layer, the heavily doped first type fingers and the heavily doped second type fingers.

More preferably, in the photodetector according to the present invention, the at least one heavily doped first type finger and the at least one heavily doped second type finger are alternately partially embedded in the epitaxial layer to a small depth.

More preferably, the photodetector according to the present invention comprises a substrate to support upper layers; an epitaxial layer formed on the substrate; N heavily doped first type fingers partially embedded in the epitaxial layer to a small depth; N+1 heavily doped second type fingers partially embedded in the epitaxial layer to a small depth to alternate with the N heavily doped first type fingers; and a regrown epitaxial layer formed on the epitaxial layer, the N heavily doped first type fingers and the N+1 heavily doped second type fingers, wherein N is a natural number, and the first type and the second type are doped with opposite type elements.

Further, the present invention provides a method of manufacturing a photodetector, comprising (A) forming an epitaxial layer on a substrate; and (B) forming at least one heavily doped first type finger and at least one heavily doped second type finger partially embedded in the epitaxial layer to a small depth, wherein the first type and the second type are in opposite states of being doped.

Preferably, the above method further comprises (C) forming a regrown epitaxial layer on the epitaxial layer, the heavily doped first type fingers and the heavily doped second type fingers.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view schematically showing a general photodetector integrated circuit;

FIG. 2 is a sectional view showing a conventional photodetector;

FIG. 3 is a graph showing optical efficiency and frequency characteristics varying with finger spaces in the conventional photodetector;

FIG. 4a is a top plan view showing a photodetector according to the present invention;

FIG. 4b is a sectional view taken along the line A-A′ of FIG. 4a;

FIG. 5 is a graph showing frequency characteristics varying with finger spaces in the conventional photodetector and the photodetector according to the present invention;

FIG. 6 is a graph showing optical efficiency varying with finger spaces in the conventional photodetector and the photodetector according to the present invention;

FIG. 7 is an energy diagram showing an energy level varying with the depth from the surface of the photodetector according to the present invention; and

FIGS. 8a to 8i are sectional views showing a process of manufacturing the photodetector according to the present invention.

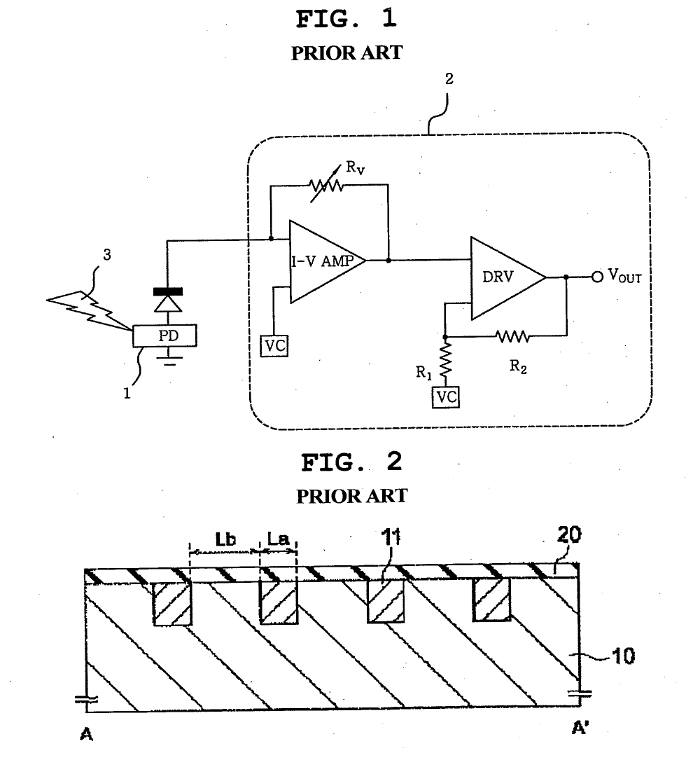

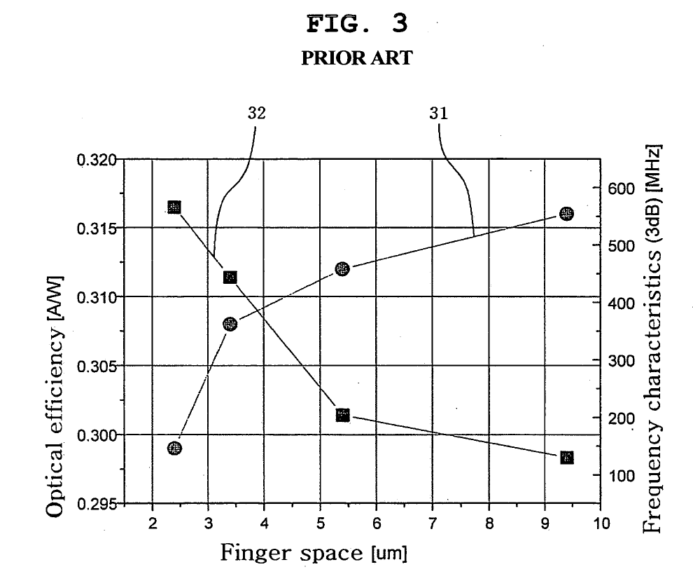

### DESCRIPTION OF THE PREFERRED EMBODIMENTS

Hereinafter, a detailed description will be given of a photodetector and a method of manufacturing the photodetector, according to the present invention, with reference to the appended drawings.

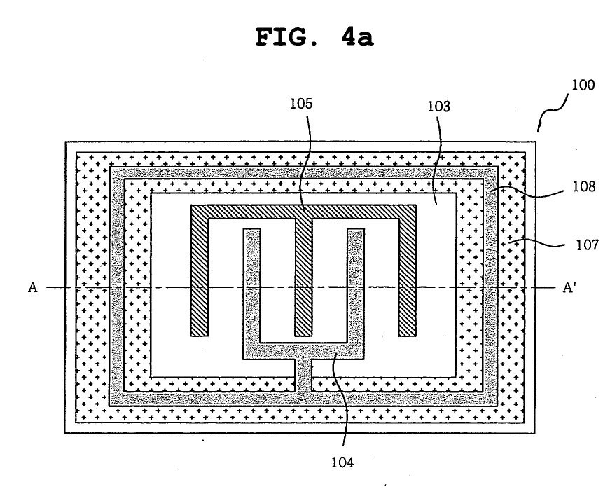

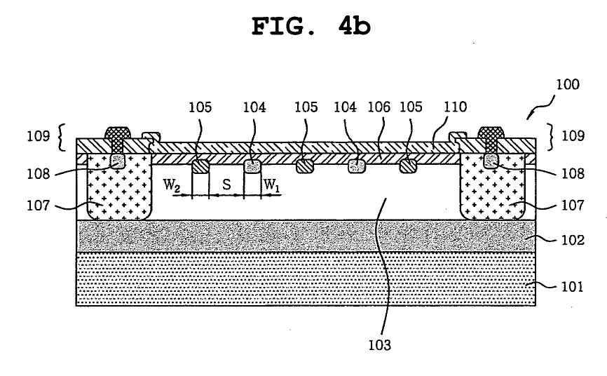

FIG. 4a is a top plan view of the photodetector according to the present invention, and FIG. 4b is a sectional view of the photodetector taken along the line A-A′ of FIG. 4a.

As shown in FIGS. 4a and 4b, the photodetector 100 of the present invention includes a substrate 101, a heavily doped first type buried layer 102 disposed on the substrate 101, an epitaxial layer 103 disposed on the heavily doped first type buried layer 102, at least one heavily doped first type finger 104 and at least one heavily doped second type finger 105 partially embedded in the epitaxial layer 103 to a small depth, and a regrown epitaxial layer 106 disposed on the epitaxial layer 103, the heavily doped first type fingers 104 and the heavily doped second type fingers 105. Further, the photodetector 100 has a first type well 107 formed in the epitaxial layer 103 and the regrown epitaxial layer 106 which are disposed outside the heavily doped first type fingers 104 and the heavily doped second type fingers 105 to be connected to the heavily doped first type buried layer 102. In addition, a heavily doped first type electrode unit 108 partially embedded in the first type well 107 to a small depth, and a circuit unit 109 connected to the heavily doped first type electrode unit 108 to externally transmit electric signals, are provided. As such, the first type and the second type are in opposite states of being doped (e.g., if the first type is a P-type, the second type is an N-type). Also, the photodetector 100 of the present invention further comprises an anti-reflection coating layer 110 disposed on the regrown epitaxial layer 106 so that the light is not reflected from the surface thereof.

In the photodetector 100 of the present invention, the substrate 101 functions to support the upper layers. Preferably, the substrate 101 includes a silicon-based substrate, and more preferably, a substrate doped in the same type as the heavily doped first type buried layer 102 formed thereon.

The heavily doped first type buried layer 102 is formed by ion-implanting a Group III or V element on the substrate 101.

The heavily doped first type buried layer 102 includes an impurity at a concentration of about 10¹⁵-10²¹ cm⁻³, and preferably, about 10¹⁶-10¹⁷ cm⁻³. If the impurity in the heavily doped first type buried layer 102 has a concentration less than 10¹⁵ cm⁻³, resistance of the heavily doped first type buried layer 102 increases, and thus, the frequency characteristics of the photodetector 100 are decreased. On the other hand, if the impurity in the heavily doped first type buried layer 102 has a concentration exceeding 10²¹ cm⁻³, an energy level may be deformed into an impurity band structure, and thus a structure thereof becomes undesirable.

Alternatively, in the cases where the substrate 101 is doped in the same type as the heavily doped first type buried layer 102 and includes an impurity having a sufficiently high concentration (about 10¹⁵-10²¹ cm⁻³), the substrate 101 may act as the heavily doped first type buried layer 102, and therefore, the heavily doped first type buried layer 102 need not be formed.

The epitaxial layer 103 results from epitaxial growth on the heavily doped first type buried layer 102 using a CVD (Chemical Vapor Deposition) process.

In this case, to achieve a lattice match between the heavily doped first type buried layer 102 and the epitaxial layer 103, the epitaxial layer 103 is formed of silicon, silicon carbide (SiC) or diamond, having a lattice constant similar to silicon crystals.

The epitaxial layer 103 functions to form a fingered photodiode, along with the heavily doped first type buried layer 102 and the heavily doped second type finger 105, or the heavily doped first type buried layer 102 and the heavily doped first type finger 104, so as to absorb light of about 405 nm to be transformed into electric signals. Commonly, light of about 405 nm is mostly absorbed in the range of a depth of about 0.1 μm or less from the surface of a silicon layer. Accordingly, to sufficiently absorb light of about 405 nm, the epitaxial layer 103 has a thickness of 0.2-5 μm, and preferably, about 1-3 μm. If the thickness of the epitaxial layer 103 exceeds 5 μm, it is difficult to manufacture a BJT (Bipolar Junction Transistor) to externally transmit the electric signals. Meanwhile, if the thickness of the epitaxial layer 103 is less than 0.2 μm, the light absorption region diminishes, thus lowering the optical efficiency.

The epitaxial layer 103 may grow by adding a small amount of impurity thereto during the epitaxial growth, so long as it has sufficient resistance. At this time, the impurity in the epitaxial layer 103 has a concentration of about 5×10¹⁵ cm⁻³ or less, and preferably, about 10¹²-10¹⁵ cm⁻³. If the impurity in the epitaxial layer 103 has a concentration exceeding 5×10¹⁵ cm⁻³, the optical efficiency of the photodetector 100 is decreased.

The heavily doped first type finger 104 is formed by ion-implantation of a Group III or V element in the epitaxial layer 103 to be partially embedded therein to a small depth.

Also, the heavily doped first type finger 104 has a width W₁ in the range of about 0.09-5 μm, and preferably, about 0.09-0.6 μm. Even if the heavily doped first type finger 104 is manufactured to have a width W₁ less than 0.09 μm, it does not negatively affect the characteristics of the photodetector 100. However, since such a finger is smaller than a minimal size required in the semiconductor manufacturing process, it is difficult to actually manufacture. Meanwhile, if the width W₁ of the heavily doped first type finger 104 exceeds 5 μm, the size of the finger is much larger than that of the photodetector 100, and the light absorption region diminishes, therefore resulting in lost characteristics of the fingered photodiode.

Moreover, the impurity in the heavily doped first type finger 104 has a concentration of about 10¹⁸-10²¹ cm⁻³, and preferably, about 10²⁰-10²¹ cm⁻³. When the impurity in the heavily doped first type finger 104 has a concentration less than 10¹⁸ cm⁻³, the resistance of the heavily doped first type finger 104 increases, thus deteriorating the performance of the photodetector 100. Conversely, if the impurity in the heavily doped first type finger 104 has a concentration exceeding 10²¹ cm⁻³, an energy level may be deformed into an impurity band structure, and thus a structure thereof becomes undesirable.

The heavily doped second type finger 105 is obtained by ion-implanting the element of opposite type in the heavily doped first type finger 104 in the epitaxial layer 103 to be partially embedded therein to a small depth.

Additionally, the heavily doped second type finger 105 has a width W₂ in the range of about 0.09-5 μm, and preferably, about 0.09-0.6 μm, like the heavily doped first type finger 104. Even if the heavily doped second type finger 105 is manufactured to have a width W₂ less than 0.09 μm, it does not negatively affect the characteristics of the photodetector 100. However, since such a finger is smaller than a minimal size required in the semiconductor manufacturing process, it is difficult to actually manufacture. Meanwhile, if the width W₂ of the heavily doped second type finger 105 is larger than 5 μm, the finger has a much larger size than the photodetector 100, and thus, the light absorption region diminishes, and the characteristics of the fingered photodiode become lost.

An impurity concentration in the heavily doped second type finger 105 is in the range of about 10¹⁸-10²¹ cm⁻³, and preferably, about 10²⁰-10²¹ cm⁻³. When the heavily doped second type finger 105 has an impurity concentration less than 10¹⁸ cm⁻³, resistance of the heavily doped second type finger 105 increases, thus deteriorating the performance of the photodetector 100. However, if the heavily doped second type finger 105 has an impurity concentration higher than 10²¹ cm⁻³, an energy level may be deformed into an impurity band structure, and thus a structure thereof becomes undesirable.

In a preferable embodiment, spaces S between the heavily doped first type fingers 104 and the heavily doped second type fingers 105 range from about 1 to 20 μm, and preferably, from about 1.4 to 9.4 μm. Even if the fingers 104 and 105 are manufactured to have the spaces S less than 1 μm therebetween, they do not negatively affect the characteristics of the photodetector 100 of the present invention, however, they are difficult to actually manufacture. On the other hand, if the spaces S between the fingers 104 and 105 exceed 20 μm, a low electric field is induced between the heavily doped first type finger 104 and the heavily doped second type finger 105, and hence, the frequency characteristics of the photodetector 100 are decreased.

In a more preferable embodiment, the heavily doped first type fingers 104 and the heavily doped second type fingers 105 are alternately partially embedded in the epitaxial layer 103 to a small depth. This is because the frequency characteristics of the photodetector 100 are related to the spaces S between the fingers 104 and 105 and the electric field induced therebetween, as represented by Equation 2, below:

$$Frequency Characteristics ( mobility of electrons or holes ) = \frac{( Electric Field between the Fingers )}{( Space between the Fingers )} \qquad Equation 2$$

In the cases where the heavily doped first type fingers 104 and the heavily doped second type fingers 105 are alternately formed, the high electric field is induced in the epitaxial layer 103 and the regrown epitaxial layer 106 which are disposed between the heavily doped first type fingers 104 and the heavily doped second type fingers 105, thus improving the frequency characteristics of the photodetector 100.

In a still more preferable embodiment, in the cases where the number of heavily doped first fingers 104 is N (wherein, N is a natural number), N+1 heavily doped second type fingers 105 are partially embedded in the epitaxial layer 103 to a small depth to alternate with the N heavily doped first type fingers 104. Thereby, the high electric field is induced in the epitaxial layer 103 and the regrown epitaxial layer 106 which are disposed between the outermost second type finger 105 and the first type well 107, and thus, the frequency characteristics of the photodetector 100 can be further increased.

The regrown epitaxial layer 106 results from epitaxial growth on the epitaxial layer 103, the heavily doped first type fingers 104 and the heavily doped second type fingers 105 using CVD. In this case, to achieve the lattice match of the epitaxial layer 103, the heavily doped first type finger 104 and the heavily doped second type finger 105 with the regrown epitaxial layer 106, the epitaxial layer 103 is formed of silicon, silicon carbide (SiC) or diamond having a lattice constant similar to the silicon crystals.

In addition, the regrown epitaxial layer 106 acts to form a fingered photodiode, together with the heavily doped first type finger 104 and the heavily doped second type finger 105, so as to absorb light of about 405 nm to be transformed into electric signals. Commonly, light of about 405 nm is mostly absorbed in the range of a depth of about 0.1 μm or less from the surface of a silicon layer. Accordingly, the regrown epitaxial layer 106 has a thickness of about 0.01-0.5 μm, and preferably, about 0.05-0.2 μm. Even if the regrown epitaxial layer 106 is manufactured to be thinner than 0.01 μm, it does not negatively affect the characteristics of the photodetector 100 of the present invention, however it is difficult to actually manufacture. Meanwhile, if the regrown epitaxial layer 106 has a thickness exceeding 0.5 μm, the regrown epitaxial layer 106 is outside the range of depletion region formed in the regrown epitaxial layer 106 by the heavily doped first type fingers 104 and the heavily doped second type fingers 105. Thus, the electron-hole pair created in the regrown epitaxial layer 106 may be eliminated by surface recombination (e.g., combination of a carrier by a dangling bond).

Also, so long as having sufficient resistance, the regrown epitaxial layer 106 may grow by adding a small amount of impurity thereto during the epitaxial growth. As such, the impurity in the regrown epitaxial layer 106 has a concentration of about 5×10¹⁵ cm⁻³ or less, and preferably, about 10¹²-10¹⁵ cm⁻³. If the regrown epitaxial layer 106 has an impurity concentration higher than 10¹⁵ cm⁻³, the optical efficiency of the photodetector 100 is reduced.

Alternatively, in the cases where the spaces S between the fingers 104 and 105 are sufficiently large, the depletion region able to absorb light between the heavily doped first type fingers 104 and the heavily doped second type fingers 105 is formed to have a relatively large area, thereby exhibiting high optical efficiency for light of about 405 nm. Hence, the regrown epitaxial layer 106 need not be formed in the photodetector 100.

The first type well 107 is formed by ion-implantation of a Group III or V element in the epitaxial layer 103 and the regrown epitaxial layer 106 (or the epitaxial layer 103 in the absence of the regrown epitaxial layer 106) disposed outside the heavily doped first type fingers 104 and the heavily doped second type fingers 105. Preferably, the first type well 107 is connected to the heavily doped first type buried layer 102 (or the substrate 101 doped in the first type when the first type impurity doped in the substrate 101 has a sufficiently high concentration).

The heavily doped first type electrode unit 108 is obtained by ion-implantation of a Group III or V element in the first type well 107 to be partially embedded therein to a small depth.

The circuit unit 109 is formed on the heavily doped first type electrode unit 108, and acts to externally transmit the electron-hole pair (that is, electric signal) created by light-absorption of the epitaxial layer 103 or the regrown epitaxial layer 106, along with the first type well 107 and the heavily doped first type electrode unit 108.

The anti-reflection coating layer 110 is formed in an appropriate thickness using silicon nitride on the regrown epitaxial layer 106 (or the epitaxial layer 103, the heavily doped first type fingers 104 and the heavily doped second type fingers 105 in the absence of the regrown epitaxial layer 106), so that light of about 405 nm is not reflected from the surface of the photodetector 100.

Preferably, the first type of the photodetector 100 is a P-type, and the second type thereof is an N-type. The reason is that the electrons functioning as a majority carrier when the first type is a P-type and the second type is an N-type have higher carrier mobility than the holes functioning as a majority carrier when the first type is an N-type and the second type is a P-type. Thereby, the frequency characteristics become superior.

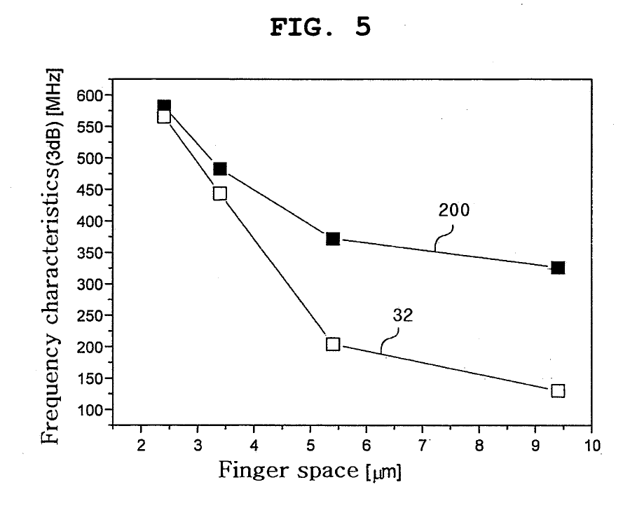

FIG. 5 is a graph showing the frequency characteristics varying with the finger spaces in the inventive photodetector and the conventional photodetector, in which a photodetector disclosed in Japanese Patent Laid-open Publication No. 2001-320075 shown in FIG. 2 is used as the conventional photodetector, and the frequency characteristics are determined by measuring the frequency of 3 dB at which a gain varying with the frequency is halved.

As shown in FIG. 5, the inventive photodetector 100 exhibits frequency characteristics 200 for light of about 405 nm at all the finger spaces S, superior to frequency characteristics 32 of the conventional photodetector disclosed in Japanese Patent Laid-open Publication No. 2001-320075.

In particular, at the wide finger spaces S causing poor frequency characteristics due to the larger mobile distance of electrons or holes, the frequency characteristics 200 of the inventive photodetector 100 are better than those 32 of the conventional photodetector disclosed in Japanese Patent Laid-open Publication No. 2001-320075.

As seen in Equation 2, since the heavily doped first type finger 104 and the heavily doped second type finger 105 are doped with opposite type elements, the electric field is induced in the epitaxial layer 103 and the regrown epitaxial layer 106 which are disposed between the heavily doped first type finger 104 (or the first type well 107) and the heavily doped second type finger 105.

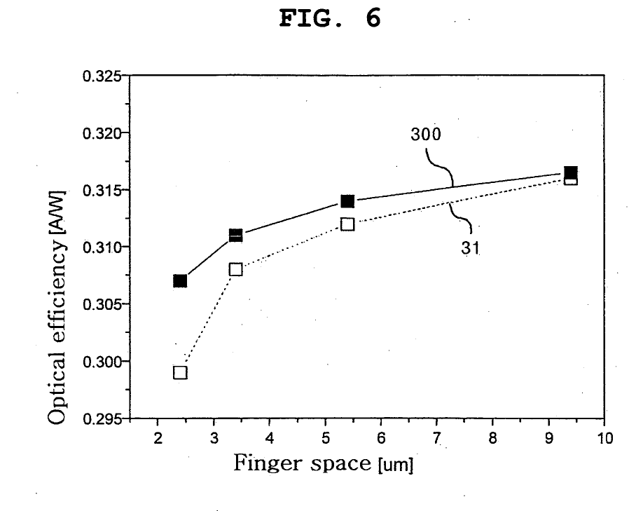

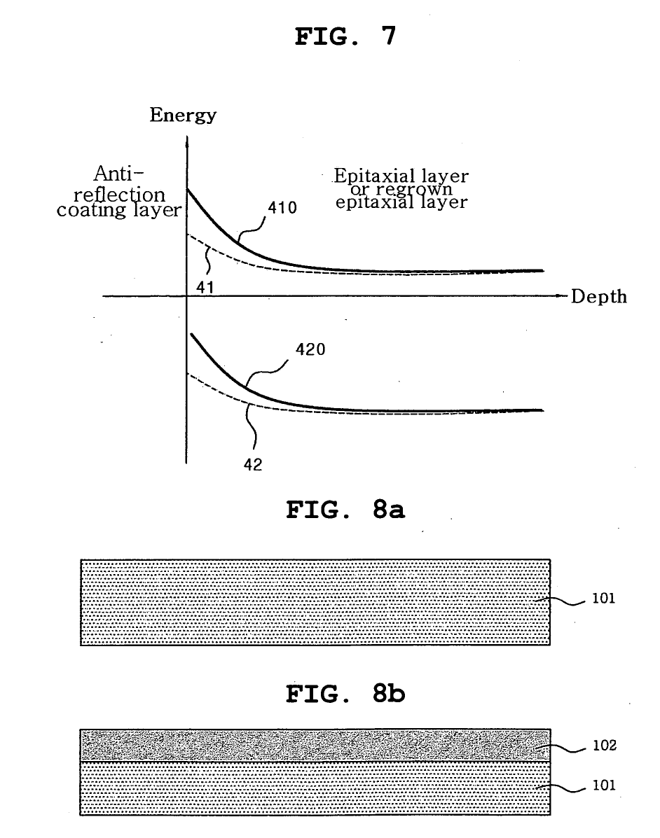

FIG. 6 is a graph showing the optical efficiency varying with the finger spaces in the inventive photodetecor and the conventional photodetector. FIG. 7 is an energy diagram showing the energy level varying with the depth from the surface of the photodetector of the present invention. As such, a photodetector disclosed in Japanese Patent Laid-open Publication No. 2001-320075 shown in FIG. 2 is used as the conventional photodetector.

As is apparent from FIG. 6, the inventive photodetector 100 has higher optical efficiency 300 for light of about 405 nm at all the finger spaces S, compared to the optical efficiency 31 of the photodetector disclosed in Japanese Patent Laid-open Publication No. 2001-320075.

Particularly, it can be shown that the optical efficiency 300 of the inventive photodetector 100 is better than that 31 of the photodetector disclosed in Japanese Patent Laid-open Publication No. 2001-320075, at the narrow finger spaces S causing poor optical efficiency due to the small light absorption region.

This is because the regrown epitaxial layer 106 is formed on the epitaxial layer 103, the heavily doped first type fingers 104 and the heavily doped second type fingers 105, whereby the region able to absorb light of about 405 nm can be enlarged.

As shown in FIG. 7, since the photodetector 100 of the present invention uses the heavily doped first type fingers 104 and the heavily doped second type fingers 105, the energy level of a conduction band 410 and a valence band 420 near the surface of the photodetector 100 of the present invention is higher than that of a conduction band 41 and a valence band 42 of the photodetector disclosed in Japanese Patent Laid-open Publication No. 2001-320075. Thus, a high electric field is induced in the epitaxial layer 103 or the regrown epitaxial layer 106. Thereby, the depletion region in the epitaxial layer 103 or the regrown epitaxial layer 106 is enlarged, and hence, the light absorption region becomes larger, resulting in increased optical efficiency for light of about 405 nm.

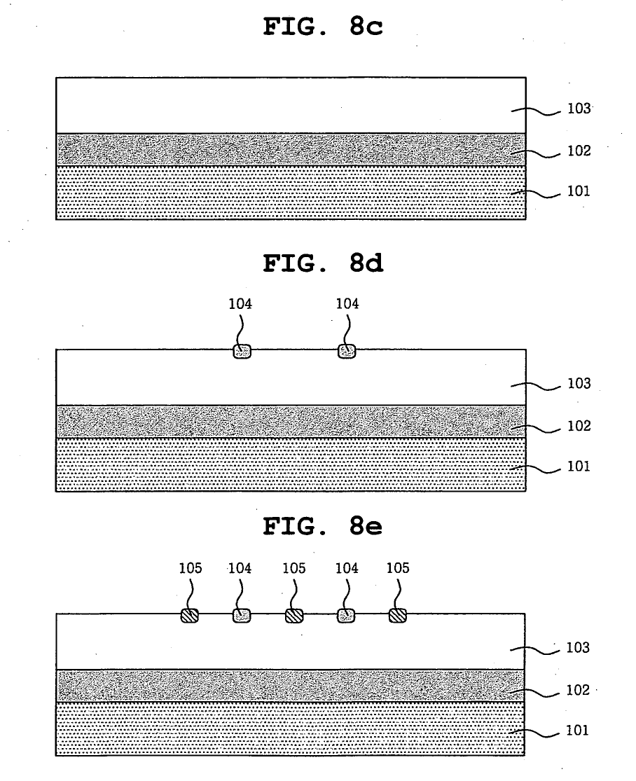

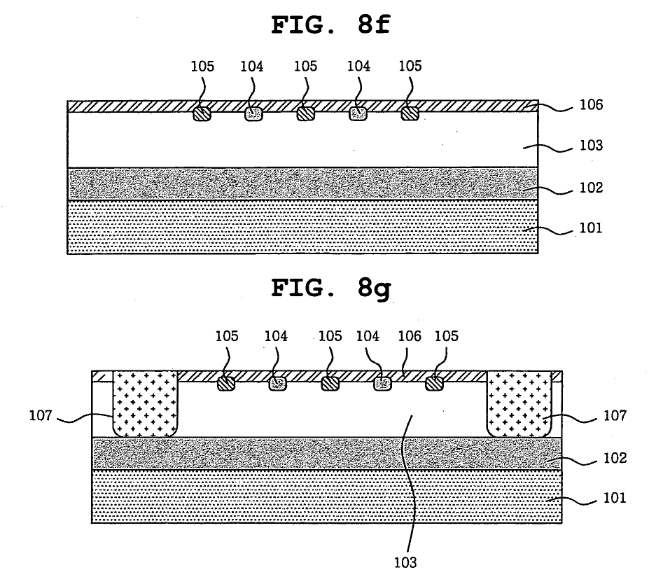

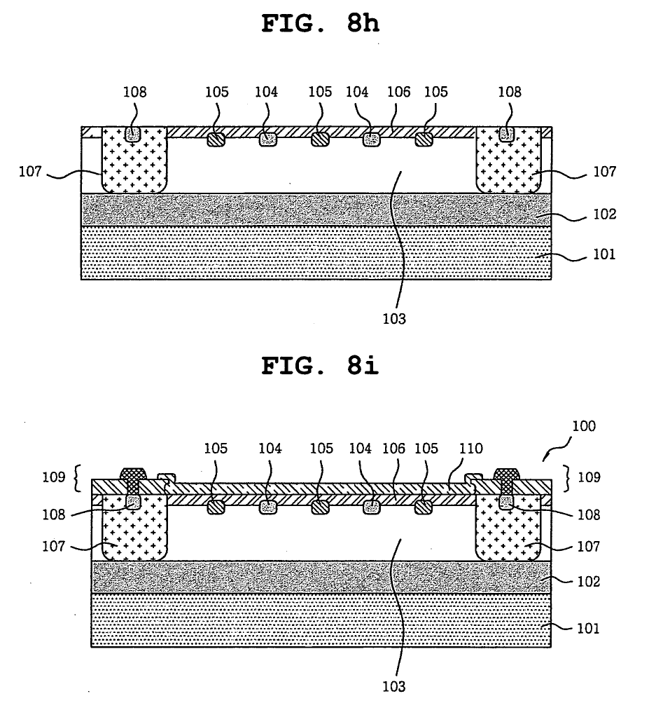

Turning now to FIGS. 8a to 8i, there is illustrated a process of manufacturing the photodetector of the present invention.

In FIG. 8a, a silicon-based substrate 101 is prepared.

In FIG. 8b, a Group III or V element is ion-implanted on the substrate 101 to form a heavily doped first type buried layer 102.

As such, it is preferable that a Group III or V element be implanted so that the heavily doped first type buried layer 102 has an impurity concentration of about 10¹⁵-10²¹ cm⁻³.

Alternatively, in the cases where the substrate 101 is doped in the same type as the heavily doped first type buried layer 102 and includes an impurity in a sufficiently high concentration (e.g., 10¹⁵-10²¹ cm⁻³), the substrate 101 can act as the heavily doped first type buried layer 102, and thus, the heavily doped first type buried layer 102 need not be formed.

In FIG. 8c, the upper surface of the heavily doped first type buried layer 102 (or the substrate 101 doped in a first type having a high impurity concentration) is subjected to epitaxial growth using CVD, to form an epitaxial layer 103.

In this case, it is preferable that the epitaxial layer 103 be formed to include an impurity of about 5×10¹⁵ cm⁻³ or less so as to exhibit sufficient resistance. Further, the epitaxial layer 103 is about 0.2-5 μm thick.

In FIG. 8d, a Group III or V element is ion-implanted in the epitaxial layer 103 to be partially embedded therein to a small depth, thereby forming at least one heavily doped first type finger 104.

The heavily doped first type finger 104 is preferably formed by implanting a Group III or V element at a concentration of about 10¹⁸-10²¹ cm⁻³. In addition, the first type finger 104 has a width W₁ of about 0.09-5 μm.

In FIG. 8e, the element of opposite type to the element in the heavily doped first type finger 104 is ion-implanted in the epitaxial layer 103 to be partially embedded therein to a small depth, to obtain at least one heavily doped second type finger 105.

As in the heavily doped first type finger 104, the heavily doped second type finger 105 is preferably formed by implanting a Group III or V element at a concentration of about 10¹⁸-10²¹ cm⁻³. In addition, the second type finger 105 has a width W₂ of about 0.09-5 μm.

In a preferable embodiment, the heavily doped first type fingers 104 and the heavily doped second type fingers 105 are formed to have spaces S of about 1-20 μm therebetween.

In a more preferable embodiment, the heavily doped first type fingers 104 and the heavily doped second type fingers 105 are alternately partially embedded in the epitaxial layer 103 to a small depth.

In a still more preferable embodiment, in the cases where the number of heavily doped first type fingers 104 is N (wherein N is a natural number), N+1 heavily doped second type fingers 105 are partially embedded in the epitaxial layer 103 to a small depth to alternate with the N heavily doped first type fingers 104.

In FIG. 8f, the upper surfaces of the epitaxial layer 103, the heavily doped first type fingers 104 and the heavily doped second type fingers 105 are subjected to epitaxial growth using the CVD process, to obtain a regrown epitaxial layer 106.

It is preferable that the regrown epitaxial layer 106 be formed to have an impurity of about 5×10¹⁵ cm⁻³ or less so as to exhibit sufficient resistance. Further, the regrown epitaxial layer 106 has a thickness of about 0.01-0.5 μm.

Alternatively, in the cases where the spaces S between the fingers 104 and 105 are sufficiently large, the depletion region able to absorb light between the heavily doped first type fingers 104 and the heavily doped second type fingers 105 is formed to have a relatively large area, and thus, the regrown epitaxial layer 106 need not be formed.

In FIG. 8g, a Group III or V element is ion-implanted in the epitaxial layer 103 and the regrown epitaxial layer 106 (or the epitaxial layer 103 in the absence of the regrown epitaxial layer 106) disposed outside the heavily doped first type fingers 104 and the heavily doped second type fingers 105, thereby forming a first type well 107.

The first type well 107 is preferably connected to the heavily doped first type buried layer 102 (or the substrate 101 doped in a first type having a high impurity concentration).

In FIG. 8h, a Group III or V element is ion-implanted in the first type well 107 to be partially embedded therein to a small depth, to form a heavily doped first type electrode unit 108.

In FIG. 8i, a circuit unit 109 is formed on the heavily doped first type electrode unit 108 to externally transmit the electric signals, and also, an anti-reflection coating layer 110 is formed using silicon nitride on the regrown epitaxial layer 106 (or the epitaxial layer 103, the heavily doped first type fingers 104 and the heavily doped second type fingers 105 in the absence of the regrown epitaxial layer 106) so that light of about 405 nm is not reflected from the surface of the photodetector 100.

Alternatively, the first type well 107, the heavily doped first type electrode unit 108 and the circuit unit 109 may not be formed. For example, a circuit may be formed to transmit electric signals through a side surface or a lower surface of the heavily doped first type buried layer 102 (or the substrate 101 doped in a first type when the first type impurity in the substrate 101 has a sufficiently high concentration) of the photodetector 100. At this time, light of about 405 nm is absorbed to the epitaxial layer 103 or the regrown epitaxial layer 106 to create the electric signals, which are then externally transmitted through the heavily doped first type buried layer 102 or the substrate 101.

As described above, the present invention provides a photodetector and a method of manufacturing the photodetector, in which a high electric field is induced in the epitaxial layer or regrown epitaxial layer by the two types of fingers, and thus, the frequency characteristics can be further improved even at the wide finger spaces as well as the narrow finger spaces.

According to the photodetector and the manufacturing method thereof of the present invention, since the regrown epitaxial layer for absorption of the short wavelength light of about 405 nm is formed on the two-type fingers, the optical efficiency can be further increased even at the narrow finger spaces as well as the wide finger spaces.

Additionally, according to the photodetector and the manufacturing method thereof of the present invention, the high electric field is induced by the two-type fingers, whereby the depletion region in the epitaxial layer or regrown epitaxial layer is enlarged, thus increasing the optical efficiency regardless of the finger spaces.

Moreover, according to the photodetector and the manufacturing method thereof of the present invention, the optical efficiency and the frequency characteristics are suitable for light of about 405 nm and all the finger spaces, which satisfy the requirements for use in high speed BD optical reproducing apparatuses.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A photodetector, comprising:
a substrate to support upper layers;
an epitaxial layer formed on the substrate;
at least one heavily doped first type finger partially embedded in the epitaxial layer to a small depth;
at least one heavily doped second type finger partially embedded in the epitaxial layer to a small depth;
a first type well formed in the epitaxial layer which is disposed outside the heavily doped first type fingers and the heavily doped second type fingers;
a heavily doped first type electrode unit partially embedded in the first type well to a small depth; and
a circuit unit formed on the heavily doped first type electrode unit,
wherein the first type and the second type are in opposite states of being doped.

2. The photodetector as set forth in claim 1, wherein the at least one heavily doped first type finger and the at least one heavily doped second type finger are alternately partially embedded in the epitaxial layer to a small depth.

3. The photodetector as set forth in claim 1, wherein the epitaxial layer has a thickness of about 0.2 to about 5 μm,
the heavily doped first type finger has a width of about 0.09 to about 5 μm,
the heavily doped second type finger has a width of about 0.09 to about 5 μm, and
the heavily doped first type fingers and the heavily doped second type fingers have spaces of about 1 to about 20 μm therebetween.

4. The photodetector as set forth in claim 1, wherein the substrate has an impurity concentration of about 10¹⁵ to 10²¹ cm⁻³,
the epitaxial layer has an impurity concentration of about 5×10¹⁵ cm⁻³ or less,
the heavily doped first type finger has an impurity concentration of about 10¹⁸ to 10²¹ cm⁻³, and
the heavily doped second type finger has an impurity concentration of about 10¹⁸ to 10²¹ cm⁻³.

5. The photodetector as set forth in claim 1, further comprising a regrown epitaxial layer formed on the epitaxial layer, the heavily doped first type fingers and the heavily doped second type fingers.

6. The photodetector as set forth in claim 5, wherein the regrown epitaxial layer has a thickness of about 0.01 to 0.5 μm.

7. The photodetector as set forth in claim 5, wherein the regrown epitaxial layer has an impurity concentration of about 5×10¹⁵ cm⁻³ or less.

8. The photodetector as set forth in claim 1, further comprising a heavily doped first type buried layer disposed between the substrate and the epitaxial layer.

9. The photodetector as set forth in claim 8, wherein the heavily doped first type buried layer has an impurity concentration of about 10¹⁵ to 10²¹ cm⁻³.

10. A photodetector, comprising:
a substrate to support upper layers;
an epitaxial layer formed on the substrate;
N heavily doped first type fingers partially embedded in the epitaxial layer to a small depth; and
N+1 heavily doped second type fingers partially embedded in the epitaxial layer to a small depth to alternate with the N heavily doped first type fingers,
wherein N is a natural number, and the first type and the second type are doped with opposite type elements.

11. The photodetector as set forth in claim 10, wherein the epitaxial layer has a thickness of about 0.2 to about 5 μm,
the heavily doped first type finger has a width of about 0.09 to about 5 μm,
the heavily doped second type finger has a width of about 0.09 to about 5 μm, and
the heavily doped first type fingers and the heavily doped second type fingers have spaces of about 1 to about 20 μm therebetween.

12. The photodetector as set forth in claim 10, wherein the substrate has an impurity concentration of about 10¹⁵ to 10²¹ cm⁻³,
the epitaxial layer has an impurity concentration of about 5×10¹⁵ cm⁻³ or less,
the heavily doped first type finger has an impurity concentration of about 10¹⁸ to 10²¹ cm⁻³, and
the heavily doped second type finger has an impurity concentration of about 10¹⁸ to 10²¹ cm⁻³.

13. The photodetector as set forth in claim 10, further comprising a first type well formed in the epitaxial layer which is disposed outside the N heavily doped first type fingers and the N+1 heavily doped second type fingers;
a heavily doped first type electrode unit partially embedded in the first type well to a small depth; and
a circuit unit formed on the heavily doped first type electrode unit.

14. The photodetector as set forth in claim 10, further comprising a regrown epitaxial layer formed on the epitaxial layer, the N heavily doped first type fingers and the N+1 heavily doped second type fingers.

15. The photodetector as set forth in claim 14, wherein the regrown epitaxial layer has a thickness of about 0.01 to 0.5 μm.

16. The photodetector as set forth in claim 14, wherein the regrown epitaxial layer has an impurity concentration of about 5×10¹⁵ cm⁻³ or less.

17. A method of manufacturing a photodetector, comprising:
(A) forming an epitaxial layer on a substrate; and
(B) forming at least one heavily doped first type finger and at least one heavily doped second type finger partially embedded in the epitaxial layer to a small depth,
wherein the first type and the second type are in opposite states of being doped.

18. The method as set forth in claim 17, wherein the step (B) is performed by forming the at least one heavily doped first type finger and the at least one heavily doped second type finger alternately partially embedded in the epitaxial layer to a small depth.

19. The method as set forth in claim 17, further comprising (C) forming a regrown epitaxial layer on the epitaxial layer, the heavily doped first type fingers and the heavily doped second type fingers.

20. The method as set forth in claim 17, further comprising:
(C) forming a first type well formed in the epitaxial layer which is disposed outside the heavily doped first type fingers and the heavily doped second type fingers;
(D) forming a heavily doped first type electrode unit partially embedded in the first type well to a small depth; and
(E) forming a circuit unit on the heavily doped first type electrode unit.

21. The method as set forth in claim 17, wherein the epitaxial layer formed in the step (A) has a thickness of about 0.2 to about 5 μm,
the at least one heavily doped first type finger and the at least one heavily doped second type finger formed in the step (B) have a width of about 0.09 to about 5 μm, and
the at least one heavily doped first type finger and the at least one heavily doped second type finger formed in the step (B) have spaces of about 1 to about 20 μm therebetween.

22. The method as set forth in claim 17, wherein the substrate has an impurity concentration of about 10¹⁵ to 10²¹ cm⁻³,
the epitaxial layer has an impurity concentration of about 5×10¹⁵ cm⁻³ or less,
the heavily doped first type finger has an impurity concentration of about 10¹⁸ to 10²¹ cm⁻³, and
the heavily doped second type finger has an impurity concentration of about 10¹⁸ to 10²¹ cm⁻³.
